(19) United States
(12) Patent Application Publication
(10) Pub. No.: US 2008/0043545 A1
(43) Pub. Date: Feb. 21, 2008

(54) Multiple Data Rate Ram Memory Controller

(76) Inventors: Jan Vink, Eindhoven (NL); Jozef Jacobus Agnes Maria Verlinden, Eindhoven (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(21) Appl. No.: 11/578,901

(22) PCT Filed: Apr. 26, 2005
(86) PCT No.: PCT/IB05/51353

§ 371 Date: Oct. 20, 2006

(30) Foreign Application Priority Data
Apr. 29, 2004 (EP) 04101851.6

(51) Int. Cl. G11C 7/00

(52) U.S. Cl. 365/193

(57) ABSTRACT

A memory controller for a multiple data rate RAM memory module is provided. Said controller comprises a PLL unit (PLL) for generating different clock phases (clk, clk90, clk180) from a reference clock (ref clk). In addition, a controllable delay unit (CDU) for delaying a strobe signal (dqs) is provided.

### FIELD OF THE INVENTION

The invention relates to multiple data rate RAM memory controller and a data processing system comprising such a memory controller.

### BACKGROUND OF THE INVENTION

With the increasing processing speed of microprocessors the memory architecture has to improve accordingly. For example a controller for Double Data Rate (DDR) Synchronous Dynamic Random Access Memory SDRAM typically comprises an interface to standard DDR SDRAM memory devices. The controller is provided to control the access to the SDRAM and serves to deal with the bus arbitration, the command interpreting, bank-interleaving and timing. The controller instructs the DDR interface when to perform writes and reads from the DDR data bus. The interface, i.e. the DDR interface, serves to maintain the bidirectional DDR data bus and assert all addresses and command signals to the SDRAM.

In FIG. 6 a basic representation of the interface between the DDR SDRAM and the controller ASIC is shown. In particular, the well known interface signals are shown. The controller ASIC issues the clock signals clkp, clkn, the address and command signal addr/cmd and the mask signal dqm. The strobe dqs as well as the data signal dq may originate from the controller ASIC for a write command or from the SDRAM for a read command.

FIG. 7 shows the corresponding timings of the interface signals of FIG. 6. In particular, the timings of a write and a read command wrt, rd are depicted. For every clock cycle two bits per pin are transferred. The rising and falling edge of the clock signal is used to capture the data with a strobe signal dqs. This strobe has the same frequency as the clock clkp. To realize a compensation for delays the strobe dqs travels with the data. Hence, the interface can be operated at speeds up to 450 Mbit/s/pin or even higher. The strobe signal dqs is generated by the data source. Therefore, for reading data the memory device SDRAM and for writing data the controller generates the strobe signal dqs. It should be noted that the alignment between strobe signal dqs and data dq is different for read and write commands.

In FIG. 8 a schematic block diagram of the relevant parts of the DDR SDRAM controller for generating multiple clock phases according to the prior art are shown. In particular, a Phase Locked Loop PLL unit PLL and a Delay Locked Loop DLL unit DLL is depicted. The PLL unit and the DLL unit are connected in series and the PLL unit outputs the clock signal clk to the DLL unit. The DLL unit serves to remove the clock skew between a processor and the SDRAM and to generate multiple clock phases from the clock signal clk to generate the write signals as described in FIGS. 6 and 7 or to capture the read data. The phases required in an interface logic (not shown) are the clock signals clk, clk90 (90°), clk180 (180°), and the strobe signals dqs90 (90°), dgs270 (270°). The strobe signal DQS originates from the external memory and is only present during reading data.

The DLL unit DLL comprises a master DLL unit MDLL and a slave DLL unit SDLL. The master DLL is a DLL unit having a feedback loop and is therefore able to lock to the incoming clock signal clk of the PLL unit PLL. Accordingly, the delay of the delay line of the DLL unit will be matched to the delay of a clock period. The delay line in the slave DLL unit SDLL is then matched to the delay line in the master DLL unit MDLL.

The slave DLL unit SDLL is used to shift the incoming strobe signal DQS by 90 degrees in phase, i.e. a quarter of a clock period, such that it can be used for capturing the incoming data. As a result, the phase shift of the strobe signal is very accurately equal to a quarter of a clock period, which is vital as the timing becomes very critical.

It should be noted, that all the above shown clock phases are required in the interface logic, which consists mainly of flip-flops. This logic serves to generate the write signals and to capture the read data. As the specific purpose of the respective clock phases is not relevant for the generation thereof, a detailed description thereof will be omitted.

However, the DLL units in the solution described above consume a considerable amount of chip area and power. This is increasingly becoming a problem especially for the interface solutions for Mobile DDR SDRAM's.

It is therefore an object of the invention to provide a memory controller for a multiple data rate RAM with a reduced required chip area and a reduced power dissipation.

This object is solved by an a multiple data rate RAM memory controller according to claim 1 and a data processing system according to claim 8.

Therefore, a memory controller for a multiple data rate RAM memory module is provided. Said controller comprises a PLL unit PLL for generating different clock phases clk, clk90, clk180 from a reference clock REFCLK. In addition, a controllable delay unit CDU for delaying a strobe signal dqs is provided.

Accordingly, the different clock phases clk, clk90 and clk180 are generated from the PLL in stead of the DLL unit as in the prior art. In addition, the prior art DLL units are replaced by single delay elements and is therefore cheaper to implement.

According to an aspect of the invention, the delay of the controllable delay unit CDU is matched to the delay of said PLL unit PLL. Accordingly, a cheap implementation is realized without sacrificing the required accuracy.

According to a preferred aspect of the invention said controllable delay unit CDU is adapted to delay a strobe signal dqs by 90 degree.

According to a further aspect of the invention said PLL unit PLL comprise a 4-phase oscillator OSC having two single delay units CDU1. Hence, the provision of the 4 phases may be implemented requiring less chip area.

According to still a further aspect of the invention said PLL unit PLL further comprises a phase comparator COMP which outputs a control signal V_{ctrl}, wherein all delay units CDU, CDU1 receive said control signal V_{ctrl} as input signal. Therefore, the signals in an interface towards a DDR SDRAM can be timed accurately.

The invention also relates to a data processing system comprising one of the above memory controller.

Further aspects of the invention are described in the dependent claims.

These and other aspects of the invention are apparent from and will be elucidated with reference to the embodiment(s) described hereinafter.

### BRIEF DESCRIPTION OF THE DRAWINGS

FIG. 1 shows a basic block diagram of the relevant parts of a DDR SDRAM controller for generating multiple clock phases according to a first embodiment;

FIG. 2 shows a schematic block diagram of an oscillator of the PLL unit of FIG. 1;

FIG. 3 shows the timings of the oscillator of FIG. 2;

FIG. 4 shows a schematic block diagram of the relevant parts of the DDR SDRAM controller for generating multiple clock phases according to a second embodiment;

FIG. 5 shows a schematic block diagram of a PLL unit of FIG. 1;

FIG. 6 shows a basic representation of the interface between the DDR SDRAM and the controller;

FIG. 7 shows the corresponding timings of the interface signals of FIG. 6; and

FIG. 8 shows a schematic block diagram of the relevant parts of the DDR SDRAM controller for generating multiple clock phases according to the prior art.

### DESCRIPTION OF THE PREFERRED EMBODIMENTS

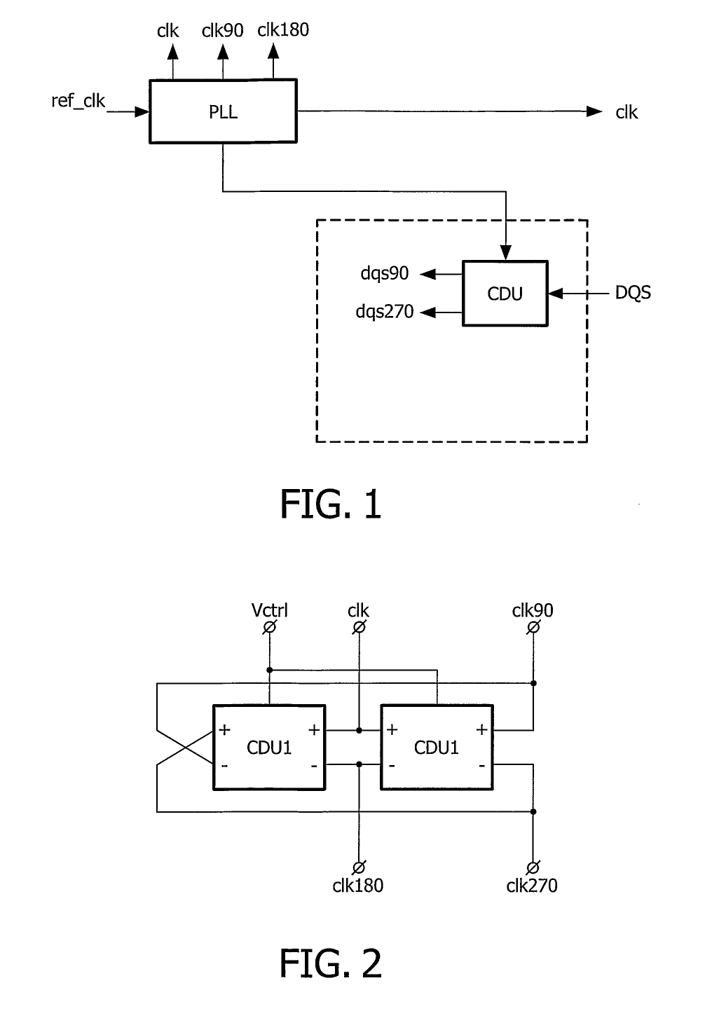

FIG. 1 shows a basic block diagram of the relevant parts of a DDR SDRAM controller for generating multiple clock phases according to a first embodiment. Such a controller is e.g. arranged between a processor and a DDR SDRAM memory module in a data processing system on a single chip or on multiple chips. The controller comprises a PLL unit PLL and a controlled delay unit CDU. These units perform the same function as the corresponding units of FIG. 8, namely to provide the different clock phases clk, clk90, and clk180 and the different phases of a strobe signal dqs90, dqs270, when data is read from the memory. Here, the delay of the controllable units CDU is matched to the delay of the 90 degree delay element in the PLL unit.

FIG. 2 shows a schematic block diagram of an oscillator OSC of the PLL unit of FIG. 1. The oscillator comprises two delay units CDU. The delay of the two controlled equal delay units CDU is controlled by the control voltage V_{ctrl}. Each delay unit can introduce a delay of ¼ T, i.e. 90 degree with regard to the input clock clk. The frequency of the oscillator will be 4 times the delay of the single delay element CDU.

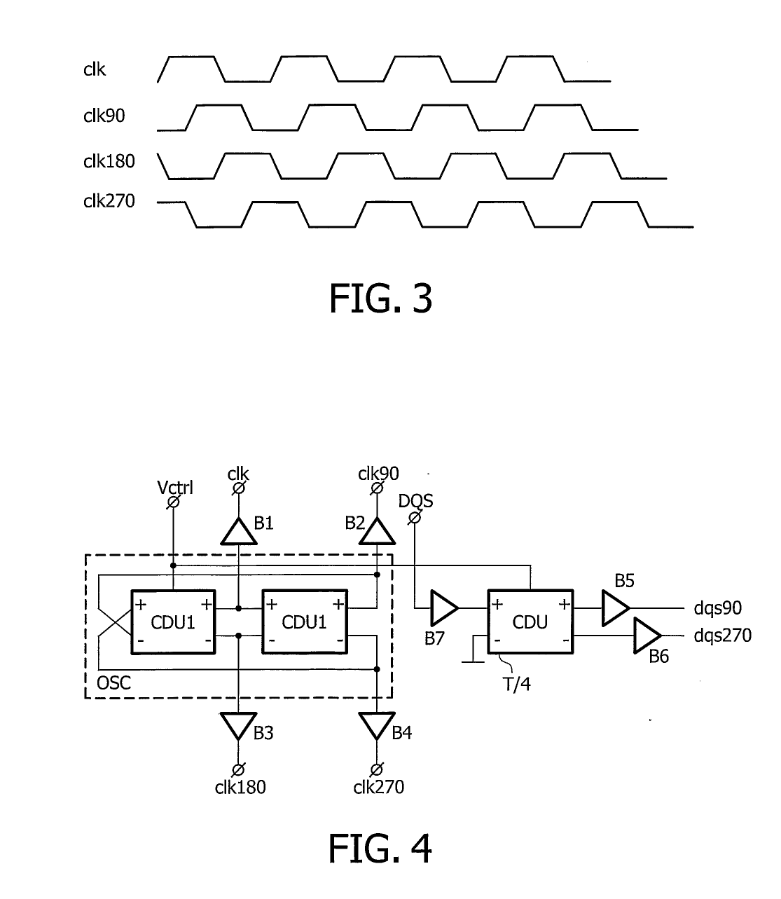

FIG. 3 shows the timings of the oscillator of FIG. 2. In particular, the signals at the nodes, i.e. the clock signal clk, the signal clk90 (being the clock signal shifted by 90 degrees), the signal clk180 (being the clock signal shifted by 180 degrees) and the signal clk270 (being the clock signal shifted by 270 degree), are shown.

FIG. 4 shows a block diagram of the relevant parts of a DDR SDRAM controller for generating multiple clock phases according to a second embodiment. Here, the oscillator OSC of FIG. 2 and a controlled delay unit CDU is shown. The purpose of this arrangement corresponds to the purpose of the arrangement of FIG. 8, namely to accurately time the signals in an interface between a processor and a DDR SDRAM memory with each other. The oscillator OSC generates the clock signals clk, clk90, clk180, clk270, i.e the clock signal and signals shifted by 90, 180, and 270 degree, respectively. The delay unit CDU receives the control signal V_{ctrl} and the strobe signal DQS as input signals and outputs dqs90 and dqs270. Preferably, the controlled delay unit CDU is a simple ¼ T delay unit. Hence, the incoming strobe signal is delayed to generate the dqs90 and dqs270 signals (being the strobe signal shifted by 90 and 270 degree), respectively. Therefore, all the phases originally shown in FIG. 8 are present. The control voltage V_{ctrl} is controlled by the feedback loop in the PLL. The buffers B1-B7 are added to translate the differential (analogue) signals of the delay units CDU in real rail-to-rail logic signals. Those signals can be used in the (not shown) interface logic mentioned above.

As the control signal V_{ctrl} is used for all three delay units CDU1, CDU, the delay unit CDU is matched to the delay in the PLL unit.

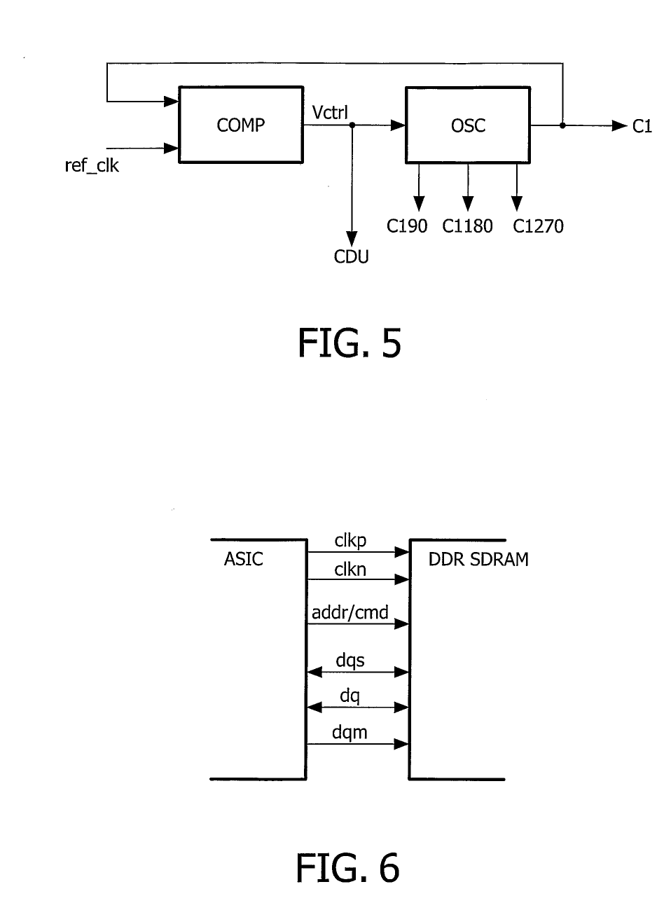

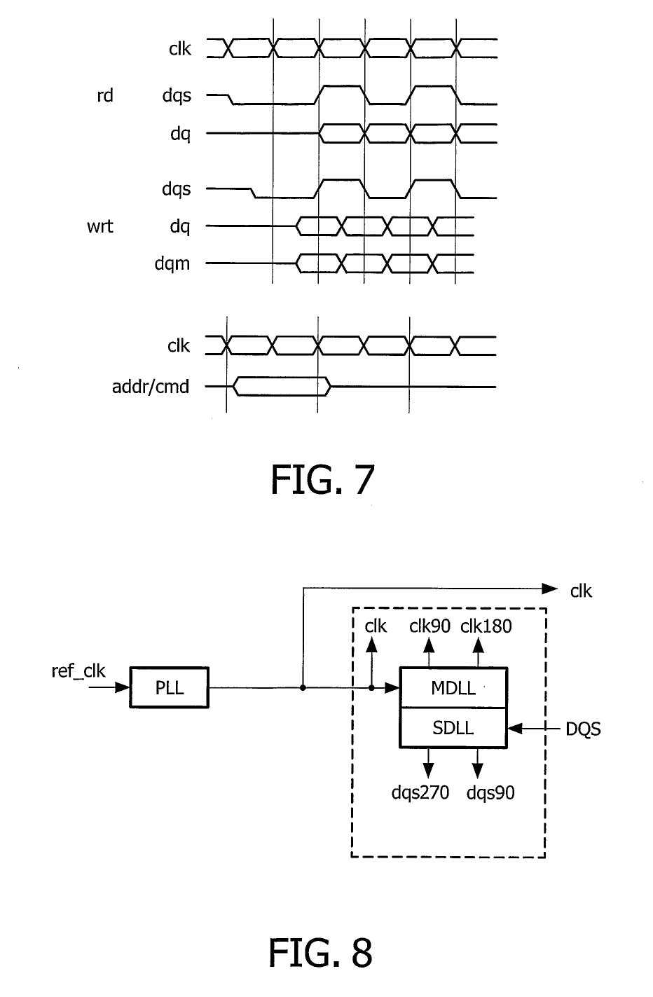

FIG. 5 shows a schematic block diagram of a PLL unit of FIG. 1. A phase comparator COMP and the oscillator OSC is shown. The output of the oscillator OSC, which may be implemented according to FIG. 2, is feed back to the input of the phase comparator COMP, where it is compared to a reference clock ref clk. The phase comparator COMP outputs the control voltage V_{ctrl}. The control voltage V_{ctrl} also serves as control input for the delay units CDU1, CDU.

Accordingly, the DDR SDRAM interface signals, like the strobe signal dqs, can be timed accurately. Additionally, simple T/4 delay elements can be employed instead of a DLL unit as in the prior art.

In other words, a solution for the physical interface towards external DDR SDRAM memories is provided, that is more efficient in terms of power and area than existing solutions. In the physical interface usually a PLL and a number of DLL's are required. The number of DLL's required, depends on the width of the external interface. As one DLL is required per byte, 4 DLL's are needed for a 32 bits interface. However, according to the invention, the DLL's are replaced by single delay elements. Since those delay elements are more power and area efficient, this improves the efficiency of the solution. Typically, the DLL's (and not standard delay elements) are used to achieve high timing accuracy. However, this accuracy is hardly influenced according to the invention.

Therefore, the area and power efficiency of the physical implementation of a DDR SDRAM interface is improved. The usual physical implementation comprises a PLL unit and 4 DLL units. According to the invention, the PLL unit comprises a 4-phase oscillator with single delay elements. As the DLL units are replaced by single delay units the area and power is approximately 8 times lower than that of 4 DLL units. While in the interfaces according to the prior art the DLL units are used to provide a very accurate delay of a fixed fraction of the clock period, the single delay units according to the invention are matched to the delay in the PLL unit to maintain the accuracy thereof.

The above described controller may be implemented for a Mobile DDR SDRAM as it has the same physical interface concept as a standard DDR SDRAM, namely two bits are transferred per clock cycle, a strobe per byte is used and the alignment between strobe and data is equal.

As the prior art DLL units contains 8 comparable delay elements, 4 in the master DLL and 4 in the slave DLL, the provision of merely one delay unit results in an area gain of 8. The delay of the single delay elements that replace the DLL's is matched to a delay element in the PLL with a delay of a quarter of a clock cycle.

According to a further embodiment of the invention the arrangement and the operation of the memory controller as described in the first and second embodiment is further adapted or implemented for a Quad Data Rate QDR SRAM. For more detailed information regarding QDR memory modules please refer to http://www.qdrsram.com.

Alternatively, the arrangement and the operation of the memory controller according to the first and second embodiment may also be implemented for other multiple data rate RAM memory controller in particular for multiple data rate SRAM memory controller.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

Furthermore, any reference signs in the claims shall not be construed as limiting the scope of the claims.

1. Memory controller for a multiple data rate RAM memory module, comprising
a PLL unit for generating different clock phases from a reference clock and
a controllable delay unit for delaying a strobe signal

2. Memory controller according to claim 1, wherein
said memory controller is adapted for double data rate SDRAM memory modules.

3. Memory controller according to claim 1, wherein
the delay of the controllable delay unit is matched to the delay of said PLL unit

4. Memory controller according to claim 1, wherein
said controllable delay unit is adapted to delay a strobe signal by 90 degree.

5. Memory controller according to claim 3, wherein
said PLL unit comprise a 4-phase oscillator having two single delay units

6. Memory controller according to claim 5, wherein
said PLL unit further comprises a phase comparator which outputs a control signal
wherein all delay units receive said control signal as input signal.

7. Memory controller according to claim 1, wherein
said memory controller is adapted for quad data rate RAM memory modules.

8. Data processing system comprising a memory controller according to claim 1.
